(19) United States
(12) Patent Application Publication
(10) Pub. No.: US 2024/0395931 A1
(43) Pub. Date: Nov. 28, 2024

(54) SEMICONDUCTOR DEVICES

(71) Applicant: SAMSUNG ELECTRONICS CO., LTD., Suwon-si (KR)

(72) Inventors: Seongjae BYEON, Suwon-si (KR); Younggeun Song, Suwon-si (KR); Wonsok Lee, Suwon-si (KR); Juho Lee, Suwon-si (KR)

(21) Appl. No.: 18/425,196

(22) Filed: Jan. 29, 2024

(30) Foreign Application Priority Data
May 25, 2023 (KR) 10-2023-0067397

(51) Int. Cl. H01L 29/78; H01L 29/10; H10B 12/00

(52) U.S. Cl. CPC H01L 29/7827; H01L 29/1033; H10B 12/30

(57) ABSTRACT

A semiconductor device includes a substrate; a channel pattern on the substrate, the channel pattern having sidewalls extending in a vertical direction perpendicular to a surface of the substrate and a lower portion connecting lower portions of two sidewalls facing each other in a horizontal direction; a gate insulation layer pattern and a first conductive layer pattern sequentially stacked laterally on an inner sidewall of the channel pattern; and a second conductive layer pattern contacting at least an uppermost surface and an upper outer sidewall of the channel pattern, the second conductive pattern being spaced apart from the first conductive layer pattern.

### CROSS-REFERENCE TO RELATED APPLICATION

This application claims priority under 35 USC § 119 to Korean Patent Application No. 10-2023-0067397, filed on May 25, 2023, in the Korean Intellectual Property Office (KIPO), the contents of which are incorporated by reference herein in their entirety.

### BACKGROUND

### 1. Field

Embodiments relate to a semiconductor device.

### 2. Description of the Related Art

For high integration of a semiconductor device, the semiconductor device may include vertical channel transistors including channels disposed in a vertical direction perpendicular to a surface of a substrate. An end of each of a channel in the vertical channel transistor may be electrically connected to a capacitor.

### SUMMARY

The embodiments may be realized by providing a semiconductor device including a substrate; a channel pattern on the substrate, the channel pattern having sidewalls extending in a vertical direction perpendicular to a surface of the substrate and a lower portion connecting lower portions of two sidewalls facing each other in a horizontal direction; a gate insulation layer pattern and a first conductive layer pattern sequentially stacked laterally on an inner sidewall of the channel pattern; and a second conductive layer pattern contacting at least an uppermost surface and an upper outer sidewall of the channel pattern, the second conductive pattern being spaced apart from the first conductive layer pattern.

The embodiments may be realized by providing a semiconductor device including a substrate; a first conductive layer pattern on the substrate, the first conductive pattern extending in a first direction parallel to an upper surface of the substrate; a channel pattern on the first conductive layer pattern, the channel pattern having sidewalls extending in a vertical direction perpendicular to the upper surface of the substrate and a lower portion connecting lower portions of two sidewalls facing each other in the first direction, and the lower portion contacting an upper surface of the first conductive layer pattern; a gate insulation layer pattern stacked on an inner sidewall of the channel pattern; a second conductive layer pattern on the gate insulation layer pattern; a mold insulation structure on an outer sidewall of the channel pattern, the mold insulation structure including a lower mold insulation pattern and an upper mold insulation pattern stacked, the upper mold insulation pattern being spaced apart from an upper outer sidewall of the channel pattern; a third conductive layer pattern contacting at least an uppermost surface and the upper outer sidewall of the channel pattern, the third conductive layer pattern filling a space between the outer sidewall of the channel pattern and the upper mold insulation pattern; and a capacitor contacting an upper surface of the third conductive layer pattern.

The embodiments may be realized by providing a semiconductor device including a substrate; a channel pattern on the substrate, the channel pattern having sidewalls extending in a vertical direction perpendicular to a surface of the substrate and a lower portion connecting lower portions of two sidewalls facing each other in a first direction parallel to an upper surface of the substrate; a gate insulation layer pattern and a first conductive layer pattern sequentially stacked laterally on an inner sidewall of the channel pattern; a mold insulation structure on an outer sidewall of the channel pattern, the mold insulation structure extending in the first direction, wherein an upper sidewall of the mold insulation structure is spaced apart from an upper outer sidewall of the channel pattern; a filling insulation pattern on the gate insulation layer pattern and the first conductive layer pattern, the filling insulation pattern extending in a second direction perpendicular to the first direction while opposing the mold insulation structure in a horizontal direction; and a second conductive layer pattern contacting at least an uppermost surface and an upper outer sidewall of the channel pattern, the second conductive layer pattern filling a space between the filling insulation pattern and the upper sidewall of the mold insulation structure.

### BRIEF DESCRIPTION OF THE DRAWINGS

Features will become apparent to those of skill in the art by describing in detail exemplary embodiments with reference to the attached drawings in which:

FIGS. 1 to 3 are a plan view and cross-sectional views illustrating a semiconductor device according to example embodiments;

FIG. 4 is a cross-sectional view taken along line A-A′ in FIG. 1;

FIGS. 5 to 28 are plan views and cross-sectional views of stages in a method of manufacturing a semiconductor device according to an example embodiment;

FIG. 29 is a cross-sectional view of a semiconductor device according to example embodiments;

FIG. 30 is a cross-sectional view illustrating a stage in a method of manufacturing a semiconductor device according to example embodiments;

FIG. 31 is a cross-sectional view of a semiconductor device according to example embodiments; and

FIGS. 32 to 35 are cross-sectional views illustrating a method of manufacturing a semiconductor device according to example embodiments.

### DETAILED DESCRIPTION OF THE EMBODIMENTS

Hereinafter, a direction parallel to a surface of a substrate is referred to as a first direction, and a direction parallel to the surface of the substrate and perpendicular to the first direction is referred to as a second direction. In addition, a direction perpendicular to the surface of the substrate is referred to as a vertical direction.

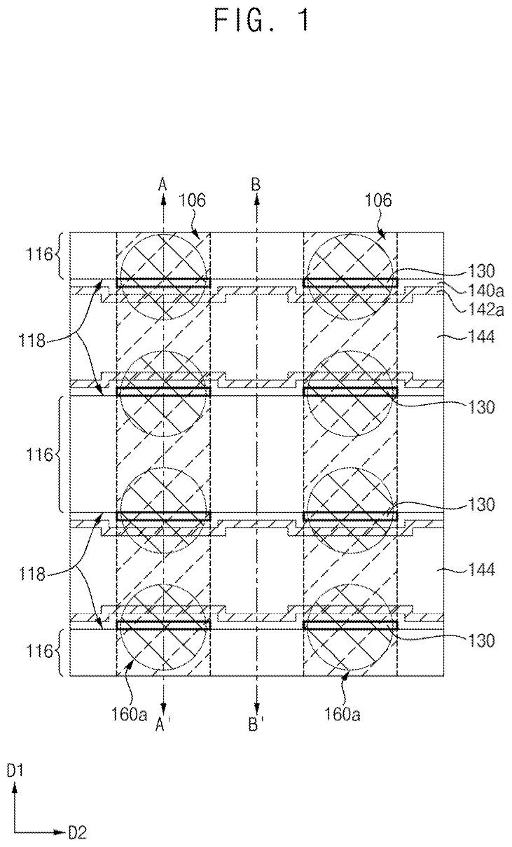

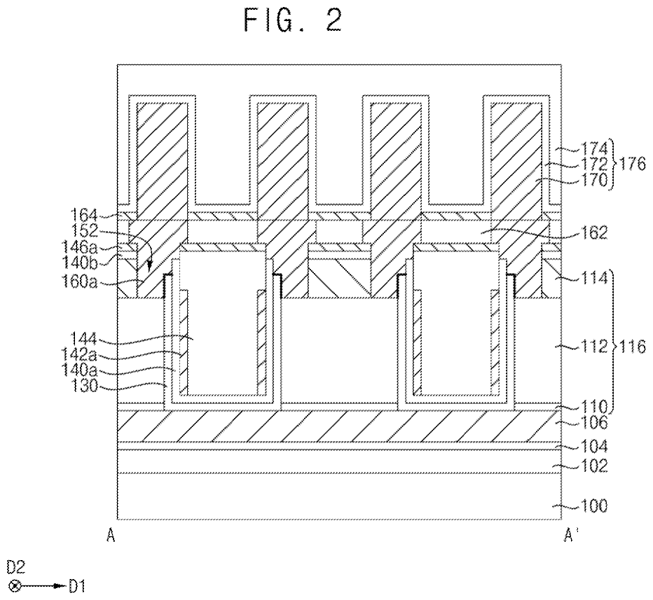

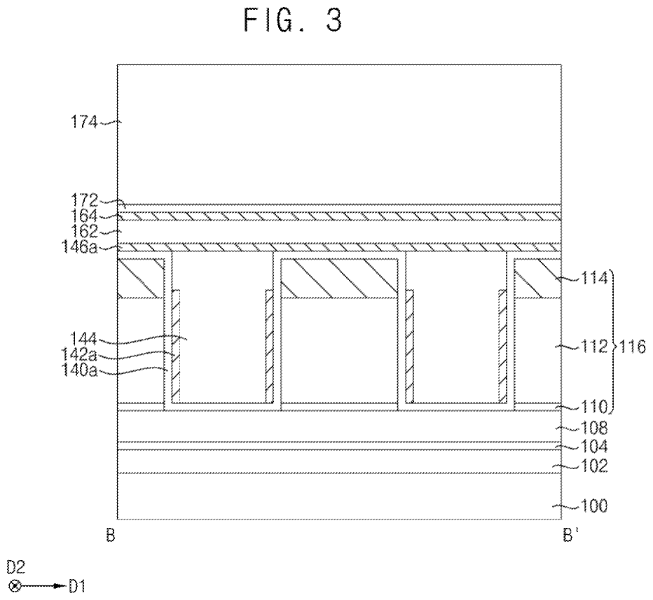

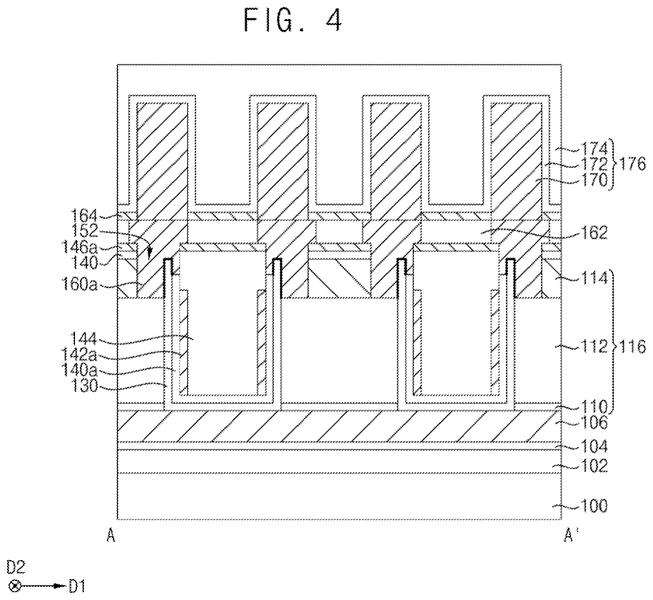

FIG. 1 is a plan view of a semiconductor device according to example embodiments. FIGS. 2 and 3 are cross-sectional views illustrating a semiconductor device according to example embodiments. FIG. 4 is a cross-sectional view illustrating a semiconductor device according to some example embodiments.

The semiconductor device may be a DRAM device. FIG. 2 is a cross-sectional view taken along line A-A′ of FIG. 1, and FIG. 3 is a cross-sectional view taken along line B-B′ of FIG. 1. FIG. 4 is a cross-sectional view taken along line A-A′ in FIG. 1. To avoid drawing complexity, elements formed on a third conductive layer pattern are omitted in FIG. 1.

Referring to FIGS. 1 to 3, the semiconductor device may include a first conductive layer pattern 106, a mold insulation structure 116, a channel pattern 130, a gate insulation layer pattern 140a, a second conductive layer pattern 142a, a third conductive layer pattern 160a and a capacitor 176 on a substrate 100. The semiconductor device may further include a first lower insulation layer 102, a second lower insulation layer 104, a third lower insulation layer 108, a filling insulation pattern 144, a first etch stop layer pattern 146a, a first insulation pattern 140b, a second insulation pattern 162 and a second etch stop layer 164. The semiconductor device may include a vertical channel transistor (VCT) on the channel pattern 130 including an oxide semiconductor.

The first lower insulation layer 102 and the second lower insulation layer 104 may be stacked on the substrate 100. The first lower insulation layer 102 may include, e.g., silicon oxide. The second lower insulation layer 104 may include, e.g., silicon nitride. An upper surface of each of the first lower insulation layer 102 and the second lower insulation layer 104 may be substantially flat.

The first conductive layer patterns 106 may be on the second lower insulation layer 104, and each of the first conductive layer patterns 106 may have a linear shape extending (e.g., lengthwise) in the first direction D1. The first conductive layer patterns 106 may be parallel to each other, and may be spaced apart from each other in the second direction D2. The first conductive layer pattern 106 may be a bit line.

The third lower insulation layer 108 may fill a space between the first conductive layer patterns 106. Upper surfaces of the first conductive layer patterns 106 and the third lower insulation layer 108 may be coplanar with each other, and may be substantially flat. In an implementation, the upper surface of the first conductive layer patterns 106 may be exposed between the third lower insulation layers 108.

In an implementation, the first conductive layer patterns 106 may include doped polysilicon, metal, conductive metal nitride, conductive metal silicide, conductive metal oxide, or a combination thereof. In an implementation, the first conductive layer patterns 106 may include doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof. Each of the first conductive layer patterns 106 may include a single layer or multiple layers of the conductive materials.

The mold insulation structures 116 may be on the first conductive layer pattern 106 and the third lower insulation layer 108, and may have a line shape extending the first direction D1. The mold insulation structure 116 may cross the first conductive layer pattern 106. A first trench 118 extending in the second direction D2 may be between the mold insulation structures 116.

The mold insulation structure 116 may have a structure in which a first mold insulation pattern 110, a second mold insulation pattern 112, and a third mold insulation pattern 114 are stacked. The first and second mold insulation patterns 110 and 112 stacked may be referred to as a lower mold insulation pattern, and the third mold insulation pattern 114 may be referred to as an upper mold insulation pattern.

In an implementation, the first mold insulation pattern 110 may include, e.g., silicon nitride. The second mold insulation pattern 112 may include, e.g., silicon oxide. The third mold insulation pattern 114 may include, e.g., silicon nitride.

The first mold insulation pattern 110 may serve as an etch stop layer. In an implementation, the first mold insulation pattern 110 may not be formed.

The channel pattern 130 may be conformally formed on a sidewall of the lower mold structure including the first mold insulation pattern 110 and the second mold insulation pattern 112 and the upper surface of the first conductive layer pattern 106 between the mold insulation structures 116. The channel pattern 130 may include two sidewalls extending in the vertical direction and a lower portion horizontally connecting lower portions of the two sidewalls facing each other in the first direction D1. In an implementation, the channel pattern 130 may have a U-shape, in the cross sectional view cut in the first direction D1.

Uppermost surfaces (e.g., both ends) of the channel pattern 130 may protrude more than an upper surface of the second mold insulation pattern 112. The uppermost surface of the channel pattern 130 may be higher than the upper surface of the second mold insulation pattern 112, and may be the same as or lower than an upper surface of the third mold insulation pattern 114. In an implementation, a vertical distance from the upper surface of the third mold insulation pattern 114 to the uppermost surface of the channel pattern 130 may be, e.g., about 0 Å to about 100 Å.

Hereinafter, a portion that is not an inner space of a U-shaped structure is referred to as an outer portion, and a portion that is the inner space of the U-shaped structure is referred to as an inner portion. In addition, a portion extending in the vertical direction in the U-shaped structure is referred to as a sidewall, and a horizontal portion connected to lower portions of both sidewalls is referred to as a lower portion.

An outer sidewall of the channel pattern 130 may contact (e.g., directly contact) sidewalls of the first and second mold insulation patterns 110 and 112, and may be spaced apart from a sidewall of the third mold insulation pattern 114. In an implementation, an isolated gap may be between the outer sidewall of the channel pattern 130 and the sidewall of the third mold insulation pattern 114. In the cross-sectional view, a width in the first direction D1 of the third mold insulation pattern 114 facing the channel pattern 130 may be less than a width in the first direction D1 of the second mold insulation pattern 112 therebelow. Widths in the first direction D1 of the first to third mold insulation patterns 110, 112 and 114 not facing the channel pattern 130 may be substantially the same.

A bottom of the channel pattern 130 may contact the upper surface of the first conductive layer pattern 106. A plurality of channel patterns 130 may be spaced apart from each other in the second direction D2. The channel patterns 130 may not be on the third lower insulation layer 108. The mold insulation structure 116 may be between the channel patterns 130 in the first direction D1, and the channel patterns 130 may be aligned in in the first direction D1.

The channel pattern 130 may include an oxide semiconductor material. In an implementation, the channel pattern 130 may include, e.g., InxGayZnzO, InxSnyZnzO, InxZnyO, ZnxO, ZnxSnyO, ZnxOyN, ZrxZnySnzO, HfxInyZnzO, GaxZnySnzO, AlxZnySnzO, YbxGayZnzO, or a combination thereof In an implementation, the channel pattern 130 may include InxGayZnzO. In an implementation, the channel pattern 130 may be amorphous state.

The gate insulation layer pattern 140a may be on an inner sidewall of the channel pattern 130. The gate insulation layer pattern 140a may be on surfaces of the channel pattern 130 and the mold insulation structure 116. In an implementation, the gate insulation layer pattern 140a may have the U-shape, in the cross-sectional view cut in the first direction D1.

The gate insulation layer pattern 140a may include metal oxide having a dielectric constant higher than a dielectric constant of silicon nitride. In an implementation, the gate insulation layer pattern 140a may include, e.g., aluminum oxide, zirconium oxide, hafnium oxide, or titanium oxide.

An uppermost surface (e.g., both ends) of the gate insulation layer pattern 140a on the channel pattern 130 may be higher than the upper surface of the second mold insulation pattern 112, and may be lower than the upper surface of the third mold insulation pattern 114.

In an implementation, as shown in FIG. 2, the uppermost surface of the gate insulation layer pattern 140a on the channel pattern 130 may be higher than the uppermost surface of the channel pattern 130.

In an implementation, as shown in FIG. 4, the uppermost surface of the gate insulation layer pattern 140a on the channel pattern 130 may be lower than the uppermost surface of the channel pattern 130. In an implementation, an upper portion of the inner sidewall of the channel pattern 130 may not be covered by the gate insulation layer pattern 140a, and thus may be exposed.

In an implementation, a first insulation pattern 140b may be on the upper surface of the third mold insulation pattern 114. The first insulation pattern 140b may include a material that is the same as a material of the gate insulation layer pattern 140a.

The second conductive layer pattern 142a may be on an inner sidewall of the gate insulation layer pattern 140a. Second conductive layer patterns 142a may be on opposing inner sidewalls of the U-shaped gate insulation layer patterns 140a, respectively. In an implementation, the second conductive layer pattern 142a may not be on an inner lower surface of the U-shaped gate insulation layer pattern 140a. Each of the second conductive layer patterns 142a may extend in the second direction D2. The second conductive layer pattern 142a may be a gate electrode of a vertical channel transistor. In an implementation, the second conductive layer pattern 142a extending in the second direction D2 may be a word line of the semiconductor device.

An uppermost surface of the second conductive layer pattern 142a may be higher than the upper surface of the second mold insulation pattern 112, and may be lower than the upper surface of the third mold insulation pattern 114. In an implementation, the uppermost surface of the second conductive layer pattern 142a may be lower than the uppermost surface of the channel pattern 130 and the uppermost surface of the gate insulation layer pattern 140a. In an implementation, the second conductive layer pattern 142a may face the sidewalls of the channel patterns 130 and the sidewall of the gate insulation layer pattern 140a.

One channel pattern 130 may be an active pattern, and two vertical channel transistors connected in series may be on the one channel pattern 130 serving as the active pattern.

The second conductive layer pattern 142a may include doped polysilicon, metal, conductive metal nitride, conductive metal silicide, conductive metal oxide, or a combination thereof. In an implementation, the plurality of second conductive layer patterns 142a may include, e.g., doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof.

The filling insulation pattern 144 may be on the second conductive layer pattern 142a and the gate insulation layer pattern 140a to fill an inner space of the U-shaped structure. The filling insulation pattern 144 may have a line shape extending in the second direction D2. The filling insulation pattern 144 may face the mold insulation structure 116 in the first direction D1.

An upper surface of the filling insulation pattern 144 may be coplanar with or higher than the upper surface of the third mold insulation pattern 114. The upper surface of filling insulation pattern 144 may be higher than the uppermost surfaces of the gate insulation layer pattern 140a and the channel pattern 130. In an implementation, the upper surface of the filling insulation pattern 144 may be substantially coplanar with the uppermost surface of the first insulation pattern 140b.

In an implementation, a first etch stop layer pattern 146a may be on upper surfaces of the filling insulation pattern 144 and the first insulation pattern 140b. The first etch stop layer pattern 146a may include, e.g., silicon nitride.

A first hole 152 having an isolated shape may be formed between the filling insulation pattern 144 and the third mold insulation pattern 114. At least the uppermost surface and upper outer sidewall of the channel pattern 130 may be exposed by the first hole 152. In an implementation, the second conductive layer pattern 142a may not be exposed by the first hole 152.

The third conductive layer pattern 160a may fill the first hole 152, and may protrude from an upper surface of the first etch stop layer pattern 146a. An upper surface of the third conductive layer pattern 160a may be higher than the upper surface of the mold insulation structure 116.

The third conductive layer pattern 160a may contact the uppermost surface and the upper outer sidewall of the channel pattern 130 and exposed surfaces of the gate insulation layer pattern 140a, the filling insulation pattern 144, the first etch stop layer pattern 146a, the third mold insulation pattern 114 and the first insulation pattern 140b. A bottom of the third conductive layer pattern 160a may contact the upper surface of the second mold insulation pattern 112.

The bottom of the third conductive layer pattern 160a may be lower than the uppermost surface of the second conductive layer pattern 142a. The third conductive layer pattern 160a may be spaced apart from the second conductive layer pattern 142a.

In an implementation, the third conductive layer pattern 160a may include a first portion vertically extending from the upper surface of the second mold insulation pattern 112 to a vertical level of the first etch stop layer pattern 146a and a second portion on the first portion. The second portion may be higher than the upper surface of the mold insulation structure 116. The second portion may be higher than the upper surface of the first etch stop layer pattern 146a. The third conductive layer pattern 160a may be a pad conductive layer pattern (e.g., a landing pad pattern) to be connected to the capacitor 276.

The first portion of the third conductive layer pattern 160a may contact at least the uppermost surface and the upper outer sidewall of the channel pattern 130, and may be electrically connected to the channel pattern 130. In an implementation, a contact area between the third conductive layer pattern 160a and the channel pattern 130 may have a reversed L-shape, in the cross-sectional view.

The third conductive layer pattern 160a may contact not only the uppermost surface of the channel pattern 130 but also the upper outer sidewall of the channel pattern 130, so that the contact area between the third conductive layer pattern 160a and the channel pattern 130 may increase. In an implementation, an electrical resistance between the third conductive layer pattern 160a and the channel pattern 130 may be decreased.

If a vertical height of the contact area between the upper outer sidewall of the channel pattern 130 and the third conductive layer pattern 160a were to be less than 50 Å, an effect of the electrical resistance due to increasing the contact area could be small. If the vertical height of the contact area between the upper outer sidewall of the channel pattern 130 and the third conductive layer pattern 160a were to be greater than 300 Å, an effective channel length of the vertical channel transistor could be relatively decreased. In an implementation, the vertical height of the contact area between the upper outer sidewall of the channel pattern 130 and the third conductive layer pattern 160a may be, e.g., about 50 Å to about 300 Å.

In an implementation, as shown in FIG. 2, the first portion of the third conductive layer pattern 160a may contact the uppermost surface and the upper outer sidewall of the channel pattern 130.

In an implementation, as shown in FIG. 4, the first portion of the third conductive layer pattern 160a may contact the uppermost surface, the upper outer sidewall, and the upper inner sidewall of the channel pattern 130.

The third conductive layer pattern 160a may include, e.g., doped polysilicon, metal, conductive metal nitride, conductive metal silicide, conductive metal oxide, or a combination thereof. In an implementation, the third conductive layer pattern 160a may include, e.g., doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof.

The second insulation pattern 162 may be formed on the first etch stop layer pattern 146a to fill a space between the third conductive layer patterns 160a. An upper surface of the second insulation pattern 162 and the upper surface of the third conductive layer pattern 160a may be coplanar with each other. The upper surface of the second insulation pattern 162 and the upper surface of the third conductive layer pattern 160a may be substantially flat. The second insulation layer pattern 192 may include, e.g., silicon oxide.

A contact portion between the channel pattern 130 and the third conductive layer pattern 160a may be higher than the upper surface of the second mold insulation pattern 112. In an implementation, the channel pattern 130 and the third conductive layer pattern 160a may not contact at a position lower than the upper surface of the second mold insulation pattern 112.

The contact portion between the channel pattern 130 and the third conductive layer pattern 160a may partially overlap an upper portion of the second conductive layer pattern 142a in a lateral direction.

The second mold insulation pattern 112 may include, e.g., silicon oxide, and thus the second mold insulation pattern 112 may supply reactive oxygen into the channel pattern 130 adjacent thereto. In an implementation, an oxygen vacancy included in the channel pattern 130 may be controlled by the second mold insulation pattern 112.

If reactive oxygen were to be supplied from the second mold insulation pattern 112 to the contact portion between the channel pattern 130 and the third conductive layer pattern 160a, a resistance between the channel pattern 130 and the third conductive layer pattern 160a could be increased. In an implementation, the second mold insulation pattern 112 may not overlap the contact portion between the channel pattern 130 and the third conductive layer pattern 160a.

In an implementation, as shown in FIG. 2, a height of the upper surface of the channel pattern 130 may be higher than a height of the second mold insulation pattern 112, so that an entire sidewall of the second mold insulation pattern 112 may contact the channel pattern 130. In an implementation, the reactive oxygen may be sufficiently supplied to the channel pattern 130 by the second mold insulation pattern 112. In an implementation, the vertical channel transistor may have excellent operating characteristics.

In an implementation, the contact portion between the channel pattern 130 and the third conductive layer pattern 160a may be higher than the second mold insulation pattern 112, and the reactive oxygen supplied from the second mold insulation pattern 112 into the contact portion between the channel pattern 130 and the third conductive layer pattern 160a may be decreased.

The second etch stop layer 164 may be on the second insulation pattern 162 and the third conductive layer pattern 160a. The second etch stop layer 164 may include, e.g., silicon nitride.

The capacitor 176 may pass through the second etch stop layer 164, and may contact the upper surface of the third conductive layer pattern 160a. The capacitor 176 may include a lower electrode 170, a dielectric layer 172, and an upper electrode 174 sequentially stacked. The lower electrode 170 may directly contact the upper surface of the third conductive layer pattern 160a. The lower electrode 170 may have a pillar shape or a cylinder shape.

The lower electrode 170 of the capacitor 176 may be electrically connected to the channel pattern 130 via the third conductive layer pattern 160a. In an implementation, the contact area between the channel pattern 130 and the third conductive layer pattern 160a may increase, and the electrical resistance between the third conductive layer pattern 160a and the channel pattern 130 may be decreased. In an implementation, electrical connection characteristics between the lower electrode 170 of the capacitor 176 and the channel pattern 130 may be improved, and electrical characteristics of the semiconductor device may be improved.

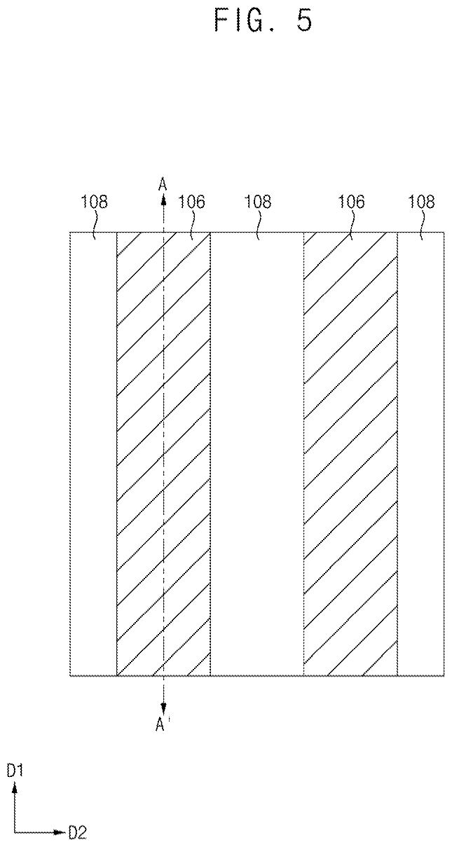

FIGS. 5 to 28 are plan views and cross-sectional views of stages in a method of manufacturing a semiconductor device according to an example embodiment.

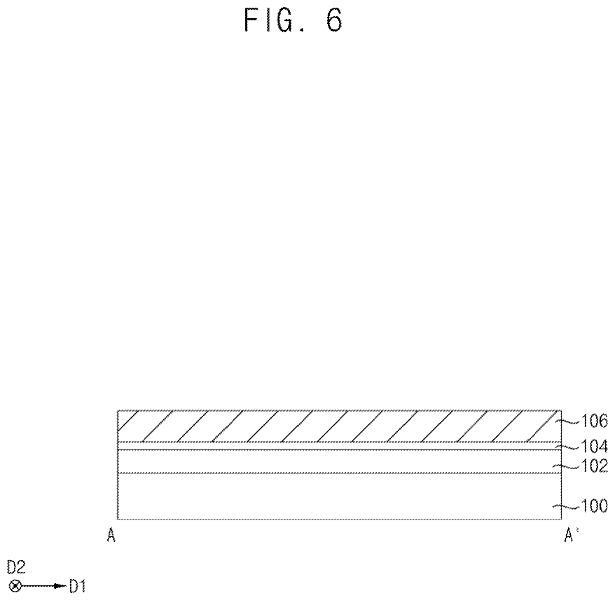

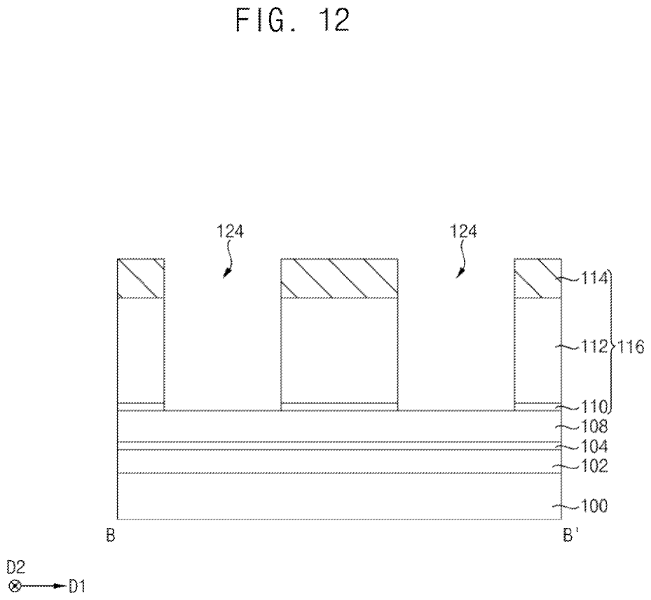

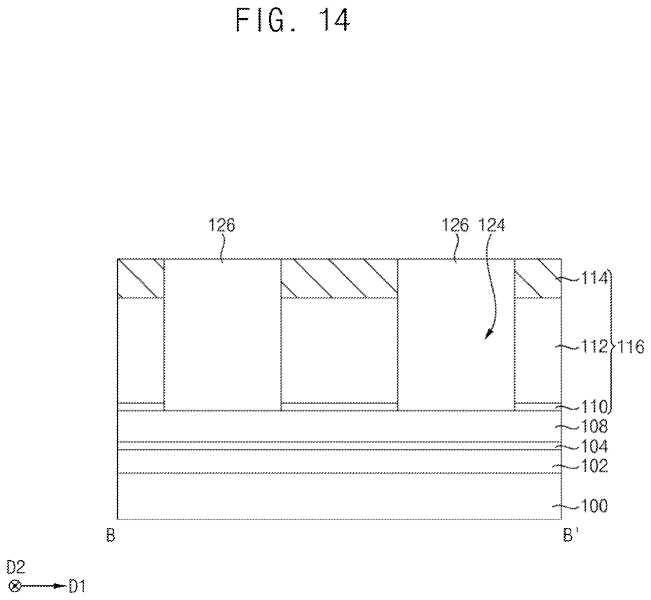

FIGS. 5, 7, 9, 15, 17, 19, 23 and 26 are plan views, and FIGS. 6, 8, 10 to 14, 16, 18, 20 to 22, 24, 25, 27, and 28 are cross-sectional views. FIGS. 6, 8, 10, 11, 14, 16, 18, 20 to 22, 24, 25, 27, and 28 are cross-sectional views taken along line A-A′ in the plan view, and FIGS. 12 and 14 are sectional views taken along line B-B′ in the plan view.

Referring to FIGS. 5 and 6, a first lower insulation layer 102 and a second lower insulation layer 104 may be formed on a substrate 100.

A first conductive pattern 106 may be formed on the second lower insulation layer 104, and the first conductive pattern 106 may have a line-shape extending in the first direction D1. A plurality of first conductive layer patterns 106 may be arranged parallel to each other, and may be spaced apart from each other in the second direction D2. A third lower insulation layer 108 may be formed between the first conductive layer patterns 106. Upper surfaces of the first conductive layer patterns 106 and the third lower insulation layer 108 may be coplanar with each other, and may be substantially flat.

In an implementation, the first and third lower insulation layers 102 and 108 may include, e.g., silicon oxide, and the second lower insulation layer 104 may include, e.g., silicon nitride.

In an implementation, the first conductive layer patterns 106 may be formed by an embossed method. In an implementation, a first conductive layer may be formed on the second lower insulation layer 104, and the first conductive layer may be patterned by a photolithography process to form the first conductive layer pattern 106. In an implementation, an insulation layer may be formed to cover the first conductive layer patterns 106, and the insulation layer may be planarized until upper surfaces of the first conductive layer patterns 106 are exposed to form the third lower insulation layer 108.

In an implementation, the first conductive layer patterns 106 may be formed by a damascene method. In an implementation, a third lower insulation layer 108 may be formed on the second lower insulation layer 104, and the lower insulation layer may be patterned by a photolithography process to form trenches. A first conductive layer may be formed on the third lower insulation layer 108 to fill the trenches, and the first conductive layer may be planarized until an upper surface of the third lower insulation layer 108 is exposed to form the first conductive layer patterns 106 in the trenches.

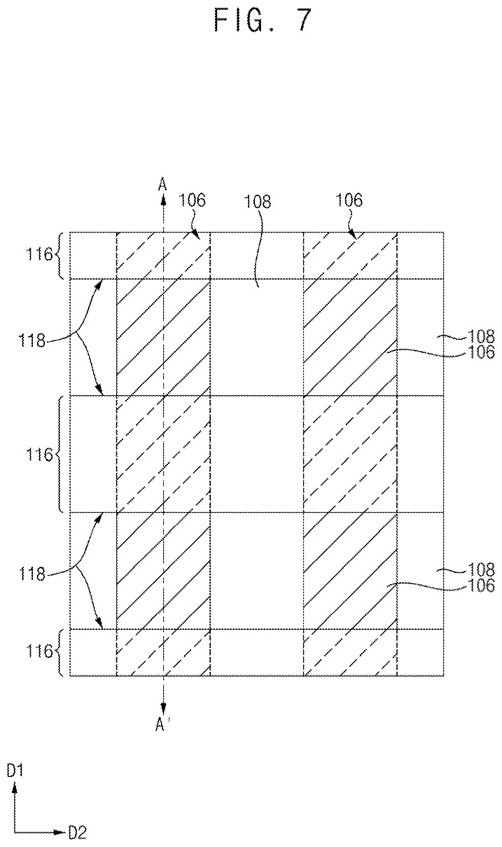

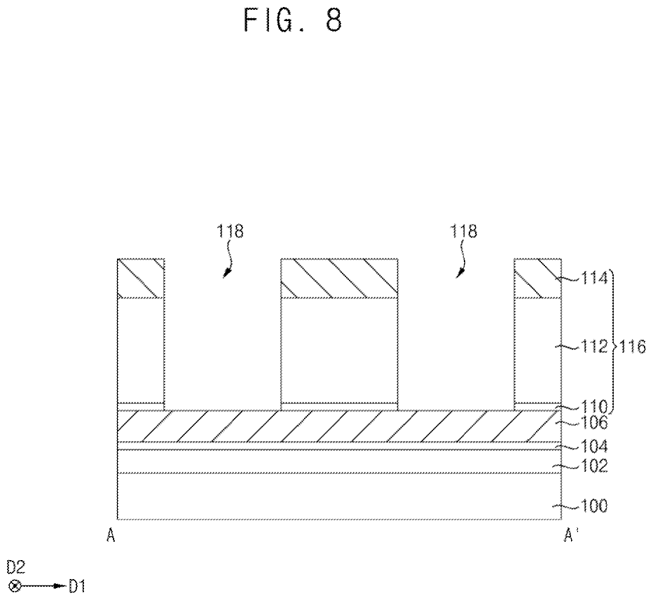

Referring to FIGS. 7 and 8, a first mold insulation layer, a second mold insulation layer, and a third mold insulation layer may be sequentially formed on the first conductive layer pattern 106 and the third lower insulation layer 108, and the first to third mold insulation layers may be patterned to form mold insulation structures 116. Each of the mold insulation structures 116 may have a structure in which a first mold insulation pattern 110, a second mold insulation pattern 112, and a third mold insulation pattern 114 are stacked.

In an implementation, the first mold insulation pattern 110 may include, e.g., silicon nitride. The second mold insulation pattern 112 may include, e.g., silicon oxide. The third mold insulation pattern 114 may include, e.g., silicon nitride. The first mold insulation pattern 110 may be an etch stop layer in a patterning process for forming the mold insulation structure 116.

The mold insulation structure 116 may have a line shape extending in the second direction D2. The mold insulation structures 116 may be spaced apart from each other in the first direction D1. A first trench 118 may be formed between the mold insulation structures 116, and the first trench 118 may extend in the second direction D2. The first conductive layer pattern 106 and the third lower insulation layer 108 may be exposed by a bottom of the first trench 118.

The mold insulation structures 116 may be a mold for forming a channel pattern, a gate insulation layer pattern and a second conductive layer pattern in subsequent processes.

A sum of heights of the first and second mold insulation patterns 110 and 112 may be substantially equal to a height of a target effective channel of a vertical channel transistor. A height of the third mold insulation pattern 114 may define a height of a lower portion of a third conductive layer pattern contacting a sidewall of the channel pattern.

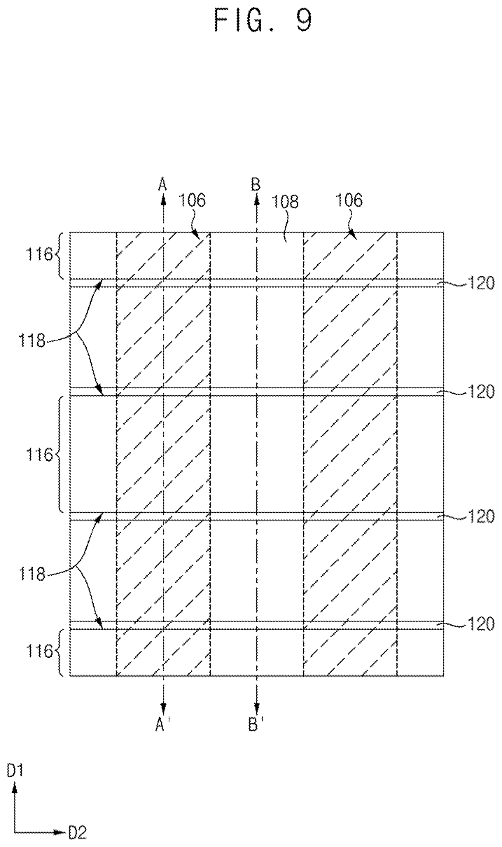

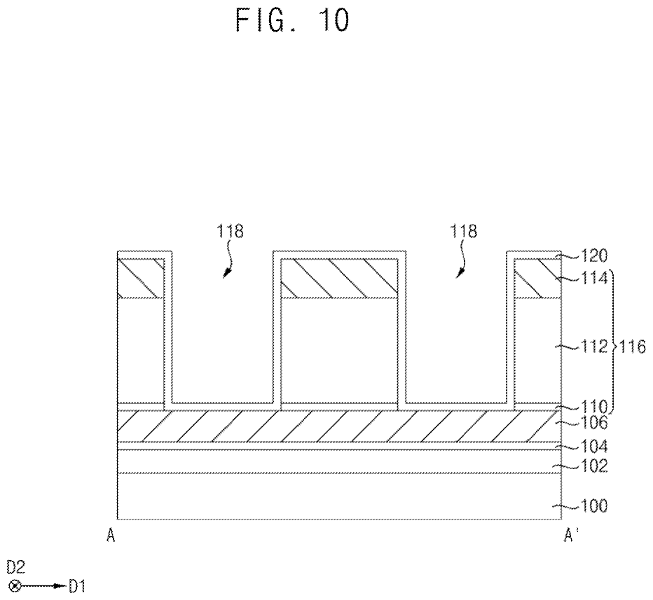

Referring to FIGS. 9 and 10, a channel layer 120 may be conformally formed on a surface of the mold insulation structure 116 and the bottom of the first trench 118. The channel layer 120 may include an oxide semiconductor layer. The oxide semiconductor layer may be a channel pattern of the vertical channel transistor in subsequent processes.

The channel layer 120 may cover the surface of the mold insulation structure 116, the upper surface of the first conductive layer pattern 106, and the upper surface of the third lower insulation layer 108. The channel layer 120 may not completely fill the first trench 118, and may be formed to have a uniform thickness along a surface profile of the first trench 118. The channel layer 120 may contact the first conductive layer pattern 106.

In an implementation, the channel layer 120 may be amorphous state. In an implementation, the channel layer 120 may include, e.g., InxGayZnzO, InxSnyZnzO, InxZnyO, ZnxO, ZnxSnyO, ZnxOyN, ZrxZnySnzO, HfxInyZnzO, GaxZnySnzO, AlxZnySnzO, YbxGayZnzO, or a combination thereof. In an implementation, the channel layer 120 may include InxGayZnzO.

In an implementation, the channel layer 120 may be formed by an atomic layer deposition (ALD) process.

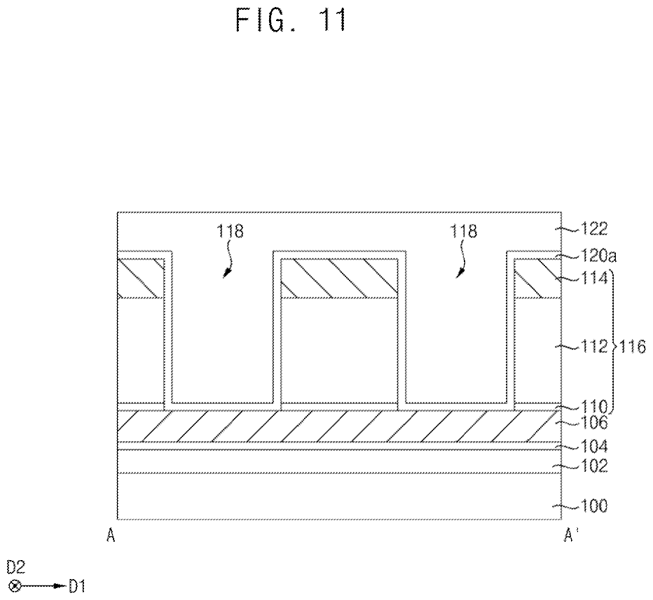

Referring to FIGS. 11 and 12, a first sacrificial layer may be formed on the channel layer 120. The first sacrificial layer may fill the first trench 118. An upper surface of the first sacrificial layer may be substantially flat. In an implementation, the first sacrificial layer may include a spin-on hard (SOH) mask. The spin-on hard mask may include amorphous carbon.

A first etch mask may be formed on the first sacrificial layer, and the first sacrificial layer may be anisotropically etched using the first etch mask to form a first sacrificial layer pattern 122. In an implementation, the channel layer 120 may be anisotropically etched using the first sacrificial layer pattern 122 as an etch mask. Accordingly, the channel layer 120 may be separated to form preliminary channel patterns 120a being spaced apart from each other in the second direction.

In an implementation, the first etch mask may be a photoresist pattern. The first etch mask may overlap the upper surface of the first conductive layer pattern 106. In an implementation, the first sacrificial layer pattern 122 may cover the upper surface of the first conductive layer pattern 106, and may extend in the first direction D1. A first opening 124 may be formed between the first sacrificial layer patterns 122 and the mold insulation structures 116. The third lower insulation layer 108 may be exposed by a bottom of the first opening 124. A lower surface of the preliminary channel pattern 120a may contact the first conductive layer pattern 106.

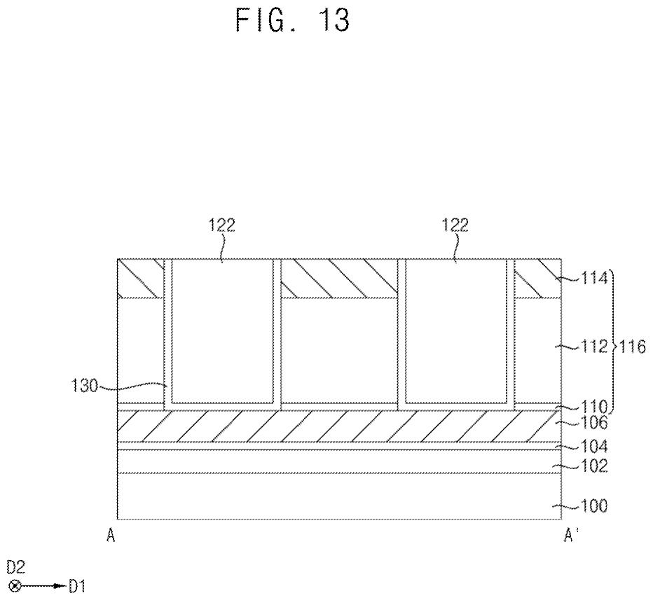

Referring to FIGS. 13 and 14, a second sacrificial layer 126 may be formed on the third lower insulation layer 108, the mold insulation structure 116, the first sacrificial layer pattern 122, and the preliminary channel pattern 120a. The second sacrificial layer 126 may fill the first opening 124. An upper surface of the second sacrificial layer 126 may be higher than an uppermost surface of the preliminary channel pattern 120a.

In an implementation, the second sacrificial layer 126 may include a material the same as a material of the first sacrificial layer pattern 122. In an implementation, the second sacrificial layer 126 and the first sacrificial layer pattern 122 may serve as one sacrificial layer pattern.

In an implementation, the second sacrificial layer 126 may include a spin-on hard mask. The spin-on hard mask may include amorphous carbon.

The second sacrificial layer 126, the first sacrificial layer pattern 122 and the preliminary channel pattern 120a may be removed to expose an upper surface of the mold insulation structure 116. In an implementation, the preliminary channel pattern 120a may be separated to form a plurality of channel patterns 130. The removing process may include an etch-back process.

Each of the channel patterns 130 may be formed along a profile of a sidewall of the mold insulation structure 116 and the upper surface of the first conductive layer pattern 106 between the mold insulation structures 116. Each of the channel patterns 130 may have a U-shape in the cross-sectional view. The channel patterns 130 may be spaced apart from each other in each of the first direction D1 and the second direction D2. A bottom of each of the channel patterns 130 may contact the first conductive layer pattern 106.

The mold insulation structure 116 may be between the channel patterns 130 in the first direction D1, and the channel patterns 130 may be aligned in the first direction D1. In an implementation, the third lower insulation layer 108 may be exposed between the channel patterns 130 in the second direction D2.

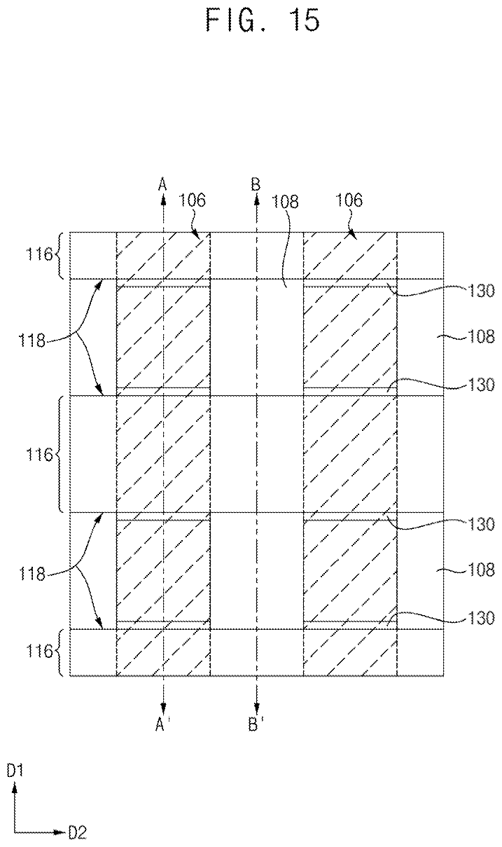

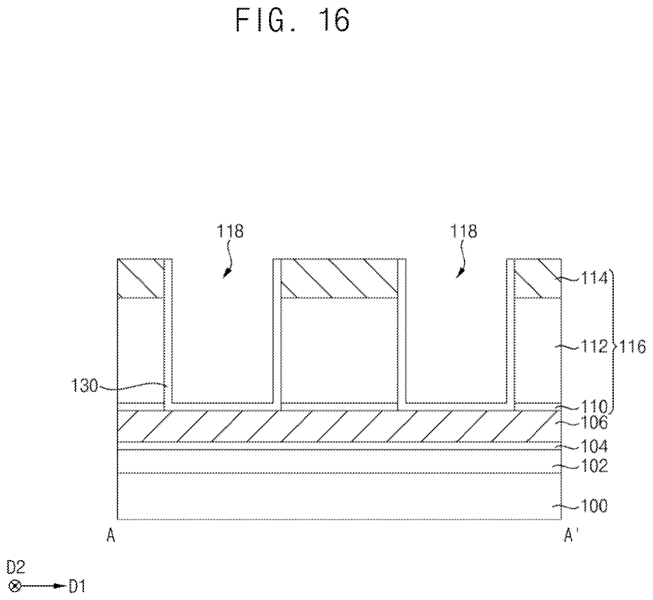

Referring to FIGS. 15 and 16, the first sacrificial layer pattern 122 and the second sacrificial layer 126 may be removed. The removing of the first sacrificial layer pattern 122 and the second sacrificial layer 126 may include an ashing process and a cleaning process. In an implementation, an upper surface of the channel pattern 130 may be exposed.

Additionally, the first trench 118 may be formed again between the mold insulation structures 116.

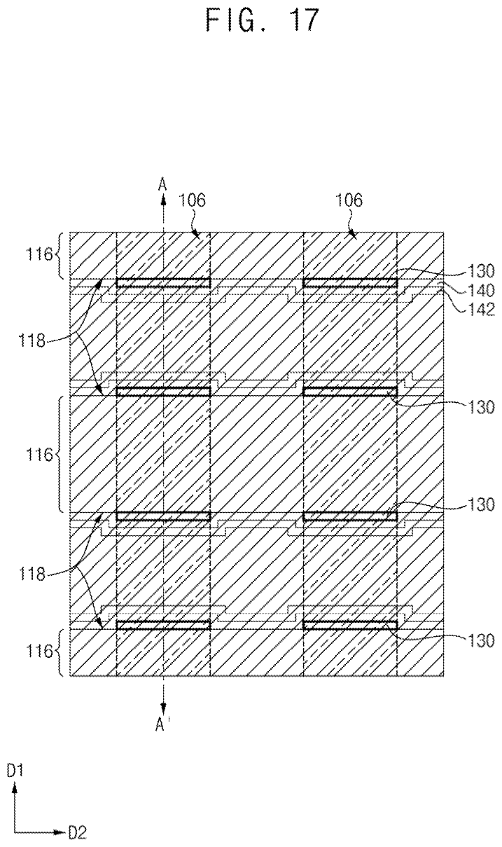

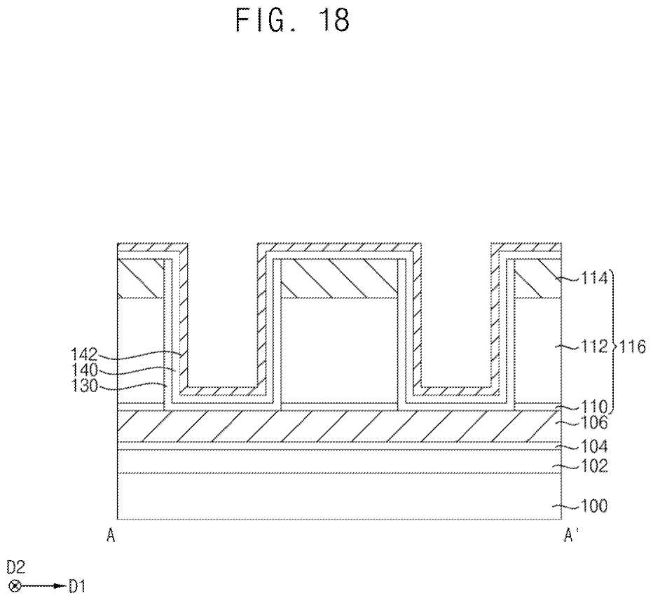

Referring to FIGS. 17 and 18, a gate insulation layer 140 and a second conductive layer 142 may be sequentially formed on the channel pattern 130, mold insulation structure 116 and third lower insulation layer 108.

The gate insulation layer 140 and the second conductive layer 142 may be conformally formed along surface profiles of the channel pattern 130, mold insulation structure 116 and third lower insulation layer 108.

The gate insulation layer 140 may include metal oxide having a dielectric constant higher than a dielectric constant of silicon nitride. In an implementation, the gate insulation layer 140 may include, e.g., aluminum oxide.

The second conductive layer 142 may include metal or metal nitride, e.g., titanium nitride.

The gate insulation layer 140 and the second conductive layer 142 may be formed by atomic layer deposition (ALD) process.

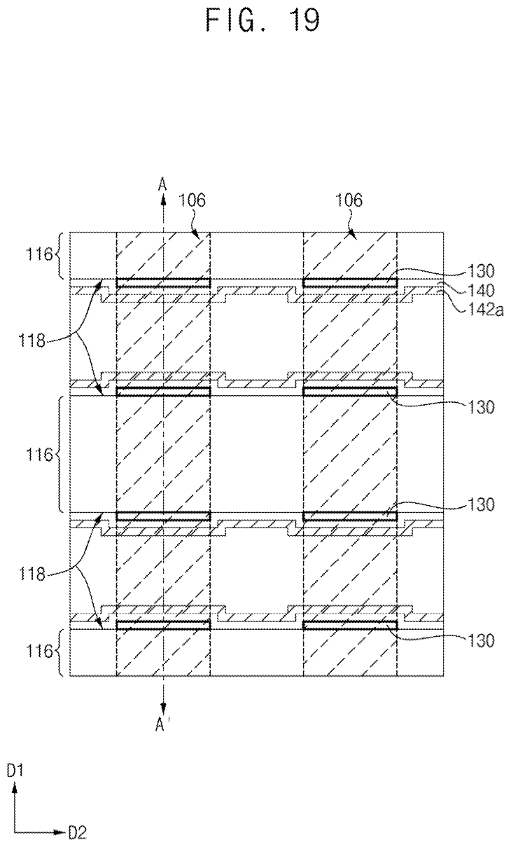

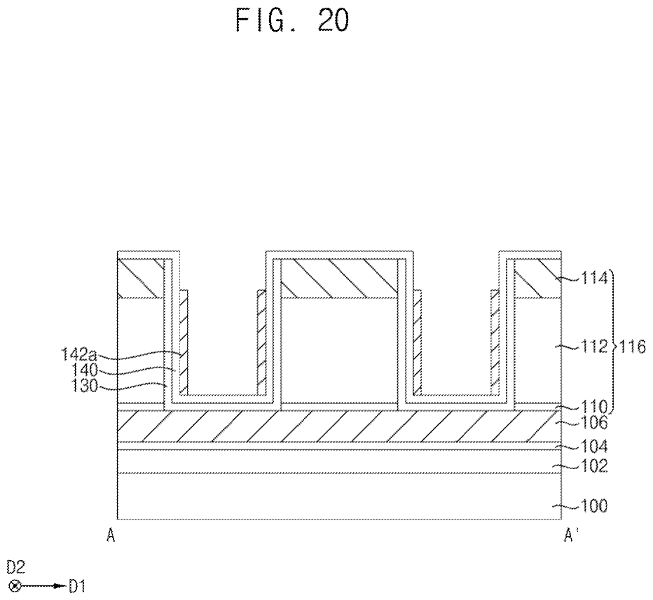

Referring to FIGS. 19 and 20, the second conductive layer 142 may be anisotropically etched, so that the second conductive layer 142 between the upper surface of the mold insulation structure 116 and the mold insulation structure 116 may be removed. In an implementation, the second conductive layers 142 may be separated to form second conductive layer patterns 142a. Each of the second conductive layer patterns 142a may be formed on the gate insulation layer 140 on the sidewall of the mold insulation structure 116. The second conductive layer pattern 142a may extend in the second direction D2. The second conductive layer pattern 142a may serve as a gate electrode of the vertical channel transistor. In an implementation, the second conductive layer pattern 142a may serve as a word line of the semiconductor device.

An upper surface of the second conductive layer pattern 142a may be coplanar with a bottom of the third mold insulation pattern 114, or may be higher than the bottom of the third mold insulation pattern 114.

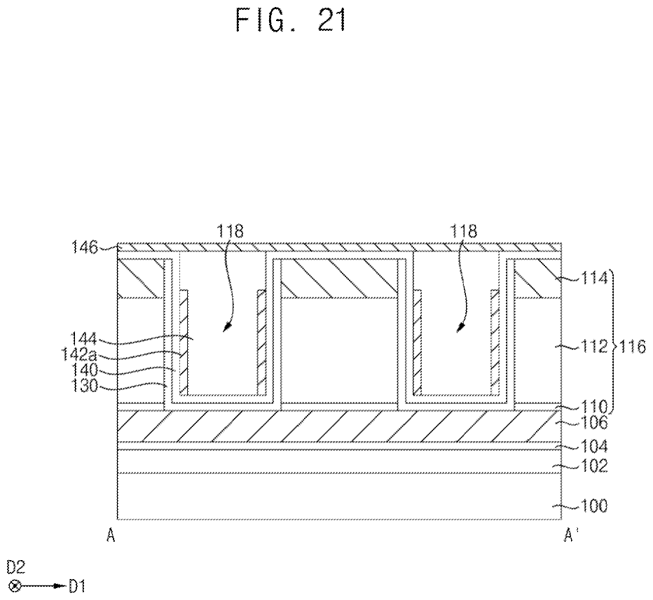

Referring to FIG. 21, a filling insulation layer may be formed on the second conductive layer pattern 142a, the gate insulation layer 140 and the mold insulation structure 116. The filling insulation layer may completely fill the first trench 118. The filling insulation layer may include, e.g., silicon oxide.

The filling insulation layer may be planarized until an uppermost surface of the gate insulation layer 140 is exposed to form a filling insulation pattern 144. The filling insulation pattern 144 may be formed on the surface of the gate insulation layer 140 and the second conductive layer pattern 142a to fill the first trench 118.

In an implementation, the planarization process may include a chemical mechanical polishing (CMP) process and/or an etch back process.

In an implementation, a liner insulation layer may be further formed on surfaces of the second conductive layer pattern 142a, the gate insulation layer 140, and the mold insulation structure 116, before forming the filling insulation layer. The liner insulation layer may protect the surface of the second conductive layer pattern 142a. The liner insulation layer may include, e.g., silicon nitride. In an implementation, a liner insulation layer pattern and the filling insulation pattern 144 may be formed on the surfaces of the gate insulation layer 140 and the second conductive layer pattern 142a in the first trench 118.

Thereafter, a first etch stop layer 146 may be formed on the gate insulation layer 140 and the filling insulation pattern 144. In an implementation, the first etch stop layer 146 may include, e.g., silicon nitride.

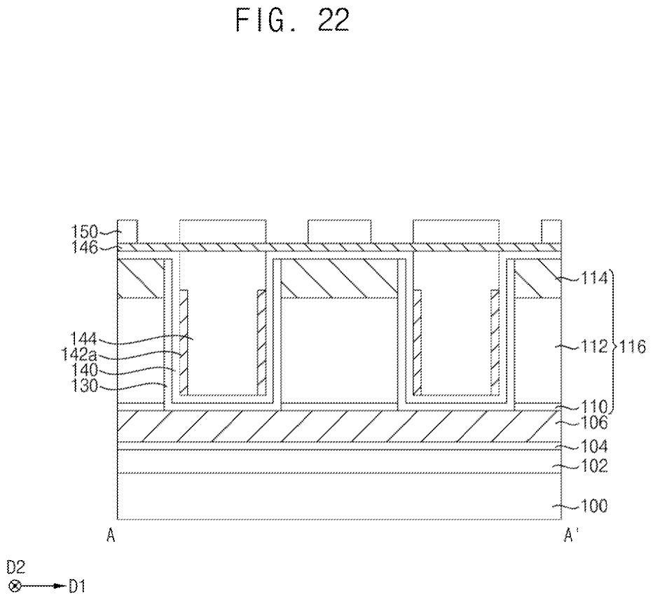

Referring to FIG. 22, a second etch mask 150 may be formed on the first etch stop layer 146.

The second etch mask 150 may be a photoresist pattern. The second etch mask 150 may include holes that may be positioned at portions facing uppermost surfaces (i.e., both ends) of the channel patterns 130. Each of the holes included in the second etch mask 150 may face the uppermost surface of the channel pattern 130 and a portion of the mold insulation structure 116 adjacent thereto. In an implementation, the second etch mask 150 may cover a portion facing an upper surface of the filling insulation pattern 144.

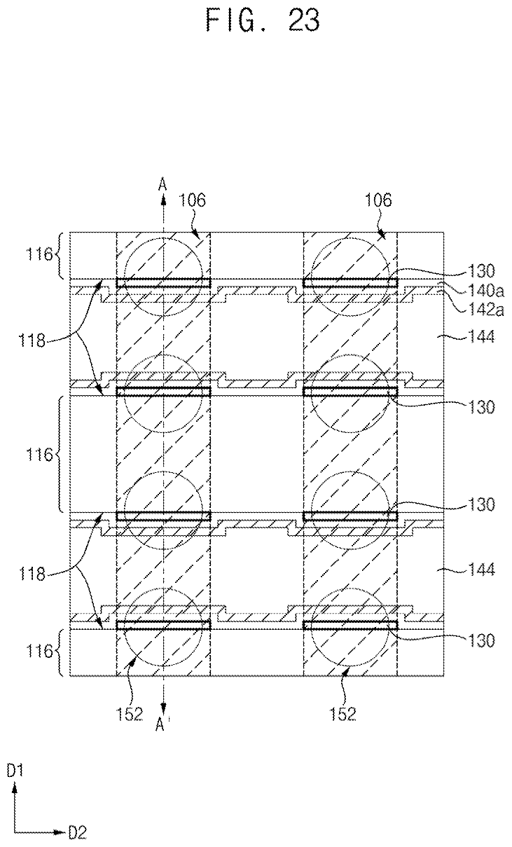

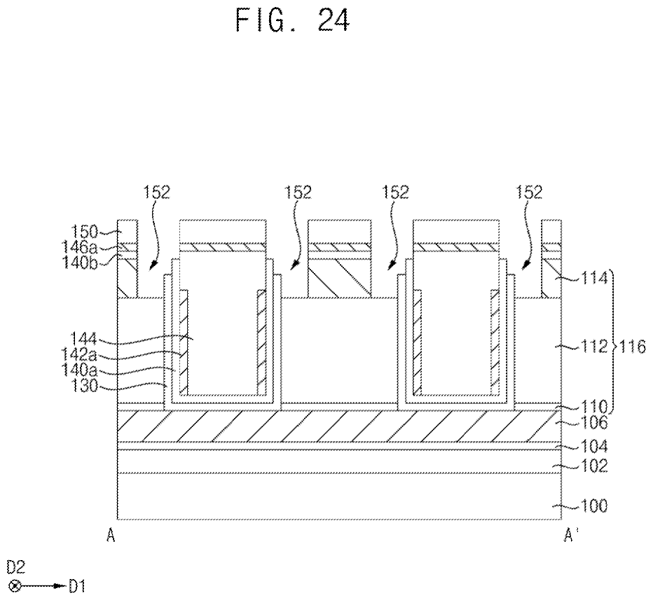

Referring to FIGS. 23 and 24, the first etch stop layer 146 and the gate insulation layer 140 may be etched using the second etch mask 150, and then the third mold insulation pattern 114 may be etched to form the first hole 152. In an implementation, a gate insulation layer pattern 140a may be formed on the channel pattern 130. The gate insulation layer remaining on the third mold insulation pattern 114 may be a first insulation pattern 140b.

An upper surface of the second mold insulation pattern 112 may be exposed by a bottom of the first hole 152. At least an upper sidewall and an upper surface of the channel pattern 130 may be exposed by a sidewall of the first hole 152. An upper portion of the gate insulation layer pattern 140a may be partially exposed by the sidewall of the first hole 152.

In the etching process for forming the first hole 152, the upper portion of the channel pattern 130 may be partially etched. After performing the etching process, the upper surface of the channel pattern 130 may be coplanar with the upper surface of the third mold insulation pattern 114, or may be between the upper surface of the third mold insulation pattern 114 and an upper surface of the second mold insulation patterns 112. In an implementation, the uppermost surface of the channel pattern 130 may be higher than an uppermost surface of the second conductive layer pattern 142a.

In an implementation, a vertical distance from the upper surface of the third mold insulation pattern 114 to the uppermost surface of the channel pattern 130 may increase, and an exposed portion of the sidewall of the channel pattern 130 in the first hole 152 may decrease. In an implementation, the vertical distance from the upper surface of the third mold insulation pattern 114 to the uppermost surface of the channel pattern 130 may be small. In an implementation, the vertical distance from the upper surface of the third mold insulation pattern 114 to the uppermost surface of the channel pattern 130 may be about 0 Å to about 100 Å.

In the etching process for forming the first hole 152, an uppermost surface of the gate insulation layer pattern 140a may be higher than the uppermost surface of the second conductive layer pattern 142a.

In an implementation, the uppermost surface of the gate insulation layer pattern 140a may be higher than the uppermost surface of the channel pattern 130.

In an implementation, the uppermost surface of the gate insulation layer pattern 140a may be lower than the uppermost surface of the channel pattern 130. In an implementation, the semiconductor device as shown in FIG. 4 may be manufactured by subsequent processes.

The third mold insulation pattern 114, the first insulation pattern 140b and a first etch stop layer pattern 146a may be formed on the second mold insulation pattern 112. In addition, the first etch stop layer pattern 146a may be formed on the filling insulation pattern 144.

Thereafter, the second etch mask 150 may be removed.

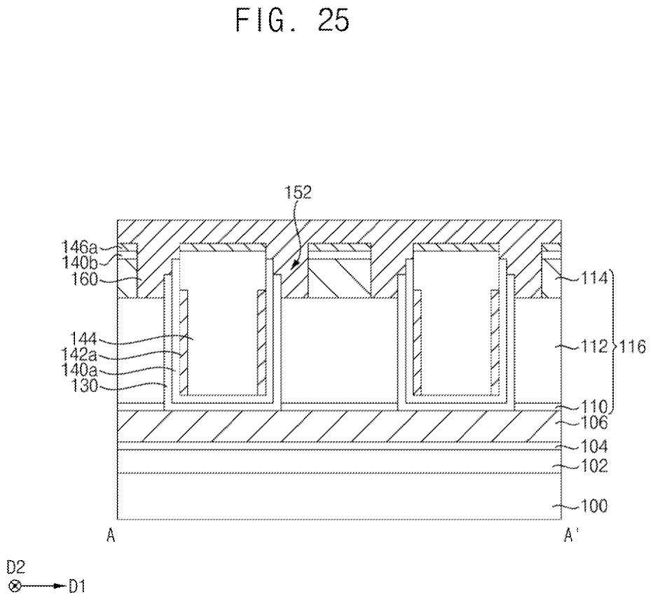

Referring to FIG. 25, a third conductive layer 160 may be formed on the first etch stop layer pattern 146a and the second mold insulation pattern 112 to fill the first hole 152.

The third conductive layer 160 filling the first hole 152 may contact the upper sidewall of the channel pattern 130 and the uppermost surface of the channel pattern 130.

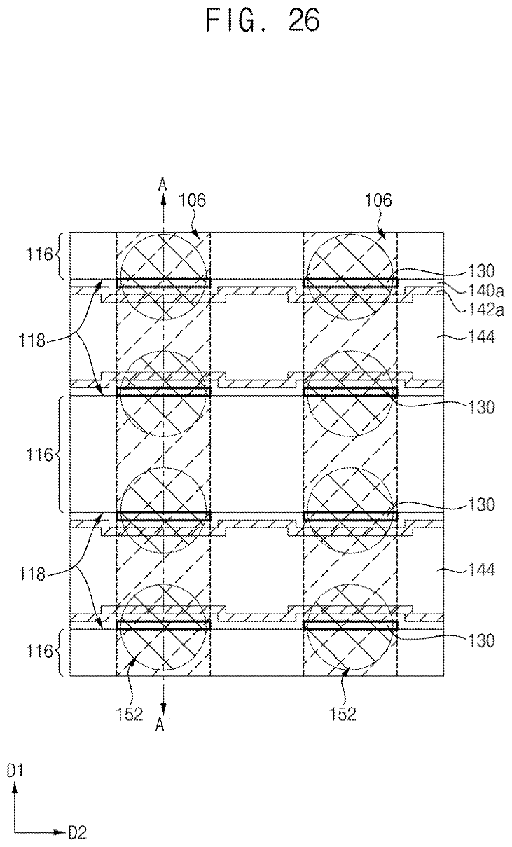

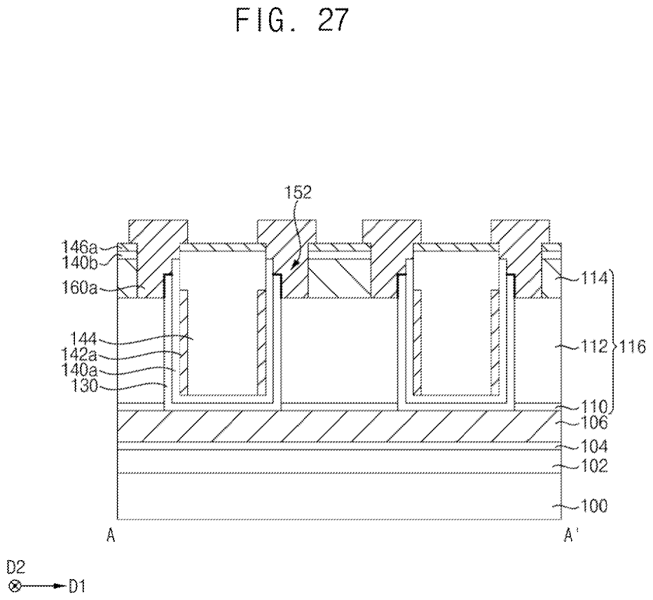

Referring to FIGS. 26 and 27, a third etch mask may be formed on the third conductive layer 160. The third etch mask may include a photoresist pattern.

The third etch mask may have an isolated shape that covers at least a portion facing each of the first holes 152. In an implementation, the third etch mask may completely cover the portion facing each of the first holes 152.

In an implementation, a photo process for forming the third etch mask may include an EUV photographic process using EUV light.

The third conductive layer 160 may be etched using the third etch mask to form a third conductive layer pattern 160a. The third conductive layer pattern 160a may contact the upper sidewall of the channel pattern 130 and the uppermost surface of the channel pattern 130. In an implementation, a contact area between the third conductive layer pattern 160a and the channel pattern 130 may have a reversed L-shape, in the cross-sectional view.

The third conductive layer pattern 160a may serve as a landing pad that contacts a lower electrode of a capacitor.

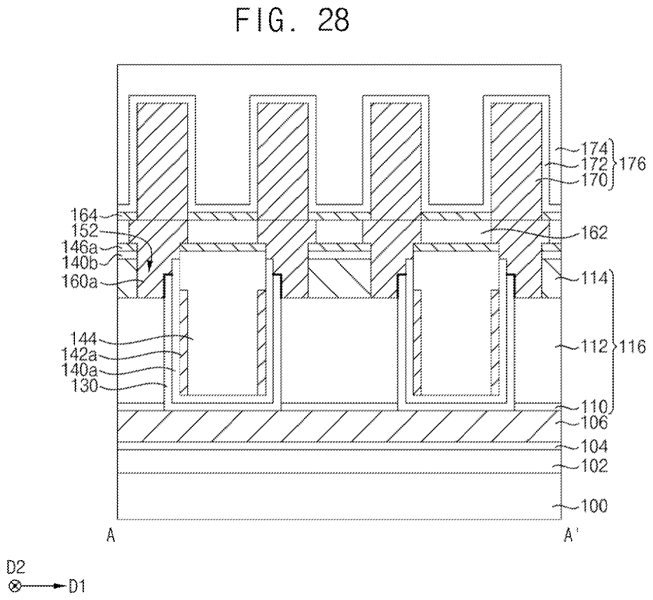

Referring to FIG. 28, a second insulation layer may be formed on the third conductive layer pattern 160a to fill a gap between the third conductive layer patterns 160a. The second insulation layer may include, e.g., silicon nitride or silicon oxide.

The second insulation layer may be planarized until an upper surface of the third conductive layer pattern 160a is exposed to form a second insulation pattern 162 filling the gap between the third conductive layer patterns 160a.

A second etch stop layer 164 may be formed on the second insulation pattern 162. The capacitor 176 may be formed through the second etch stop layer 164, and may contact the upper surface of the third conductive layer pattern 160a. The capacitor 176 may include a lower electrode 170, a dielectric layer 172 and an upper electrode 174 sequentially stacked. The lower electrode 170 may directly contact the upper surface of the third conductive layer pattern 160a. The lower electrode 170 may have a pillar shape or a cylinder shape. By the above process, the semiconductor device may be manufactured.

According to the above process, the uppermost surface and upper sidewalls of the channel pattern 130 may contact the third conductive layer pattern 160a. Accordingly, the contact area between the channel pattern 130 and the third conductive layer pattern 160a may increase, and a contact resistance between the channel pattern 130 and the third conductive layer pattern 160a may be decreased. Therefore, the semiconductor device may have excellent electrical characteristics.

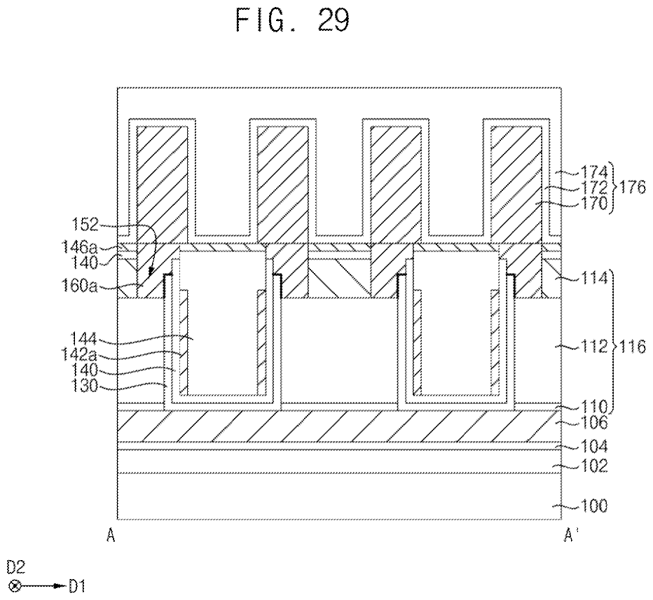

FIG. 29 is a cross-sectional view of a semiconductor device according to example embodiments.

The semiconductor device as shown in FIG. 29 may be the same as the semiconductor device described with reference to FIGS. 1 to 3, except for the second conductive layer pattern. Therefore, redundant descriptions may be omitted.

FIG. 29 is a cross-sectional view cut along the line A-A′ in the plan view.

Referring to FIG. 29, in the semiconductor device, a first hole 152 having an isolated shape may be between the filling insulation pattern 144 and the third mold insulation pattern 114.

At least an uppermost surface and an upper outer sidewall of the channel pattern 130 may be exposed by the first hole 152.

The third conductive layer pattern 160a may fill the first hole 152. An upper surface of the third conductive layer pattern 160a may be coplanar with an upper surface of the first etch stop layer pattern 146a. In an implementation, the upper surface of the third conductive layer pattern 160a may have no portion protruding from the upper surface of the first etch stop layer pattern 146a.

The third conductive layer pattern 160a may be formed on the uppermost surface and the upper outer sidewall of the channel pattern 130 and exposed surfaces of the gate insulation layer pattern 140a, the filling insulation pattern 144, the first etch stop layer pattern 146a, the third mold insulation pattern 114 and the first insulation pattern 140b. A bottom of the third conductive layer pattern 160a may contact an upper surface of the second mold insulation pattern 112.

The third conductive layer pattern 160a may contact at least the uppermost surface and the upper outer sidewall of the channel pattern 130, and may be electrically connected to the channel pattern 130.

The capacitor 176 may be formed on the third conductive layer pattern 160a, and may contact an upper surface of the third conductive layer pattern 160a. The capacitor 176 may include the lower electrode 170, the dielectric layer 172 and the upper electrode 174 sequentially stacked. The lower electrode 170 may directly contact the upper surface of the third conductive layer pattern 160a. The lower electrode 170 may have a pillar shape or a cylinder shape.

In an implementation, the first etch stop layer pattern 146a may be below the lower electrode 170 of the capacitor 176, and a second etch stop layer pattern may not be formed. In an implementation, the second insulation pattern may not be formed between the third conductive layer patterns 160a.

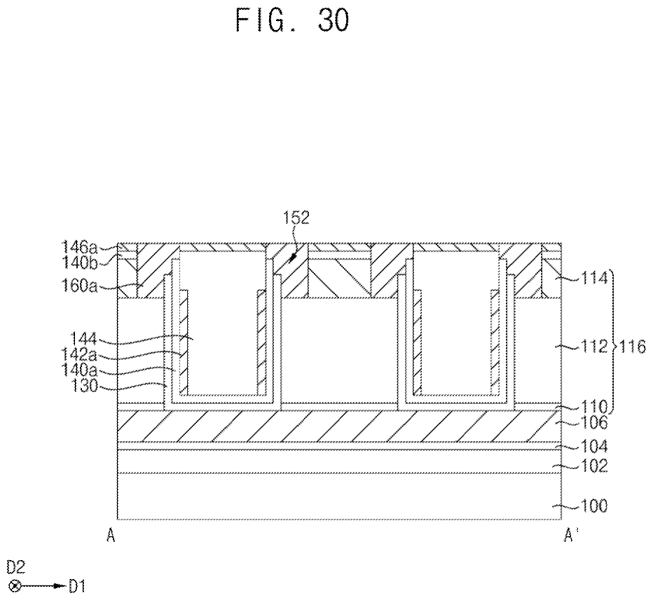

FIG. 30 is a cross-sectional view illustrating a stage in a method of manufacturing a semiconductor device according to example embodiments.

FIG. 30 is a cross-sectional view taken along the line A-A′ in the plan view.

Referring to FIG. 30, first, the process described with reference to FIGS. 5 to 25 may be performed to form the structure as shown in FIG. 25.

Thereafter, the third conductive layer may be planarized until an upper surface of the first etch stop layer pattern 146a is exposed to form a third conductive layer pattern 160a in the first hole 152. An upper surface of the third conductive layer pattern 160a may be coplanar an upper surface of the first etch stop layer pattern 146a.

In an implementation, a second etch stop layer may be formed on the third conductive layer pattern 160a and the first etch stop layer pattern 146a. In an implementation, a process for forming a second insulation pattern may be omitted.

Referring again to FIG. 29 again, the capacitor 176 may be formed on the upper surface of the third conductive layer pattern 160a. The capacitor 176 may include the lower electrode 170, the dielectric layer 172 and the upper electrode 174 sequentially stacked.

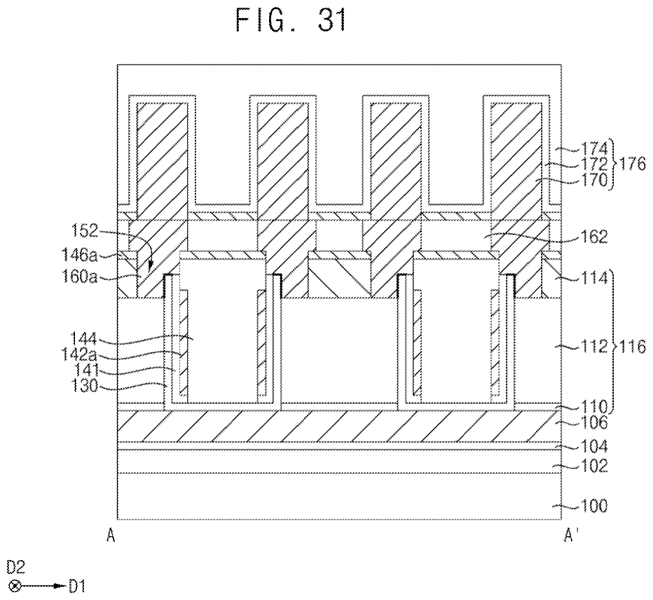

FIG. 31 is a cross-sectional view of a semiconductor device according to example embodiments.

FIG. 31 is a cross-sectional view taken along the line A-A′ in the plan view.

The semiconductor device as shown in FIG. 31 is the same as the semiconductor device described with reference to FIGS. 1 to 3, except for a gate insulation layer pattern and a first insulation pattern. Therefore, redundant descriptions may be omitted.

Referring to FIG. 31, in the semiconductor device, the gate insulation layer pattern 141 on an inner lower surface of the channel pattern 130 may have a cutting portion. The gate insulation layer pattern 141 may be on each of the inner sidewalls of the channel pattern 130. The gate insulation layer pattern 141 may extend in the second direction D2.

The second conductive layer pattern 142a may be on a sidewall of the gate insulation layer pattern 141. The gate insulation layer pattern 141 may contact a sidewall and a bottom of the second conductive layer pattern 142a. The gate insulation layer pattern 141 may have an L-shape in the cross-sectional view. The second conductive layer pattern 142a may extend in the second direction D2.

The filling insulation pattern 144 may be on the second conductive layer pattern 142a, the gate insulation layer pattern 141, and the channel pattern 130 to fill an inner space of a U-shaped structure. The filling insulation pattern 144 may have a line shape extending in the second direction D2.

In an implementation, the first etch stop layer pattern 146a may be on an upper surface of the third mold insulation pattern 114. A first insulation pattern including a material the same as a material of the gate insulation layer pattern 141 may not be on the upper surface of the third mold insulation pattern 114.

In an implementation, the first etch stop layer pattern 146a may be on an upper surface of the filling insulation pattern 144. The upper surface of the filling insulation pattern 144 and the upper surface of the third mold insulation pattern 114 may be coplanar with each other.

A first hole 152 having an isolated shape may be between the filling insulation pattern 144 and the third mold insulation pattern 114. At least an uppermost surface and upper outer sidewall of the channel pattern 130 may be exposed by the first hole 152.

The third conductive layer pattern 160a may fill the first hole 152, and may protrude from an upper surface of the first etch stop layer pattern 146a.

The third conductive layer pattern 160a may contact at least an uppermost surface and an upper outer sidewall of the channel pattern 130, and may be electrically connected to the channel pattern 130.

The second insulation pattern 162 may be formed on the first etch stop layer pattern 146a to fill a space between the third conductive layer patterns 160a.

The capacitor 176 may be on the third conductive layer pattern 160a. The capacitor 176 may include the lower electrode 170, the dielectric layer 172, and the upper electrode 174 sequentially stacked. The lower electrode 170 may directly contact an upper surface of the third conductive layer pattern 160a.

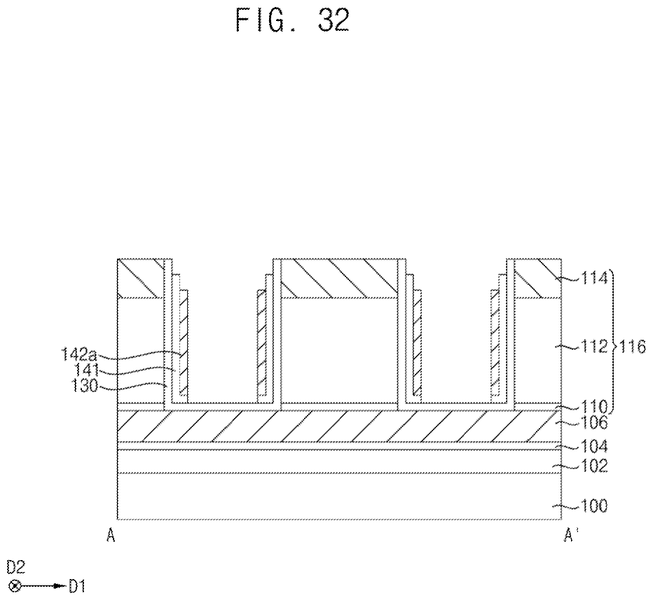

FIGS. 32 to 35 are cross-sectional views of stages in a method of manufacturing a semiconductor device according to example embodiments.

FIGS. 32 to 35 are cross-sectional views taken along line A-A′ in the plan view.

Referring to FIG. 32, first, the processes described with reference to FIGS. 5 to 18 may be performed to form the structure as shown in FIG. 18.

Thereafter, the second conductive layer 142 on an upper surface of the mold insulation structure 116 and a bottom portion of the mold insulation structures 116 may be anisotropically etched. Subsequently, the gate insulation layer 140 on the upper surface of the mold insulation structure 116 and the bottom portion of the mold insulation structure 116 may be anisotropically etched.

In an implementation, the second conductive layer 142 may be separated to form second conductive layer patterns 142a. In an implementation, the gate insulation layer 140 may be separated to form gate insulation layer patterns 141.

The second conductive layer pattern 142a and the gate insulation layer pattern 141 may be formed on an inner sidewall of the channel pattern 130. The second conductive layer pattern 142a and the gate insulation layer pattern 141 may extend in the second direction D2.

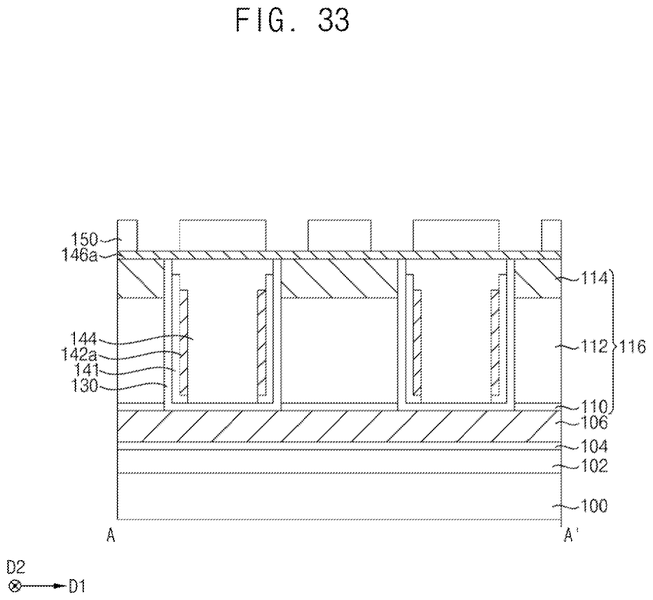

Referring to FIG. 33, a filling insulation layer may be formed on the second conductive layer pattern 142a, the gate insulation layer pattern 141 and the mold insulation structure 116. The filling insulation layer may be formed to completely fill the first trench 118. The filling insulation layer may include silicon oxide.

The filling insulation layer may be planarized until an upper surface of the mold insulation structure 116 is exposed to form a filling insulation pattern 144 filling the first trench 118.

A first etch stop layer 146 may be formed on the mold insulation structure 116 and the filling insulation pattern 144. In an implementation, the first etch stop layer 146 may include, e.g., silicon nitride.

A second etch mask 150 may be formed on the first etch stop layer 146. The second etch mask may be formed by processes as described with reference to FIG. 22.

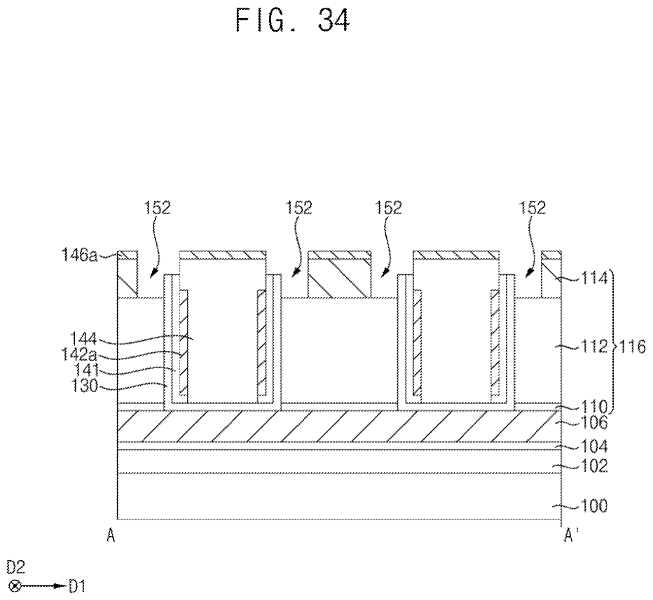

Referring to FIG. 34, the first etch stop layer 146 and the third mold insulation pattern 114 may be etched using the second etch mask 150 to form a first hole 152. An upper surface of the second mold insulation pattern 112 may be exposed by a bottom of the first hole 152. At least an upper sidewall and an uppermost surface of the channel pattern 130 may be exposed by the sidewall of the first hole 152.

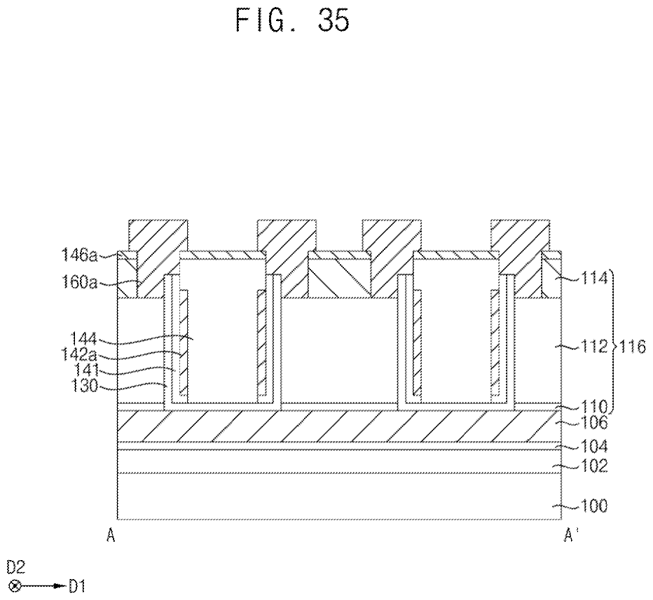

Referring to FIG. 35, a third conductive layer pattern 160a may be formed to fill the first hole 152, and may protrude from an upper surface of the first etch stop layer pattern 146a.

The third conductive layer pattern 160a may contact at least the upper sidewall of the channel pattern 130 and the uppermost surface of the channel pattern 130.

The third conductive layer pattern 160a may be formed by processes as described with reference to FIGS. 25 to 27.

The processes described with reference to FIG. 28 may be performed to form the second insulation pattern 162, the second etch stop layer 164, and the capacitor 176. Accordingly, the semiconductor device as shown in FIG. 31 may be manufactured.

By way of summation and review, electrical resistance between the channel and the capacitor may be decreased.

In the semiconductor device according to example embodiments, the conductive layer pattern electrically connected to the channel pattern in the semiconductor device may contact the uppermost surface and the upper outer sidewall of the channel pattern. The contact area between the conductive layer pattern and the channel pattern may be increased, and accordingly, the contact resistance between the conductive layer pattern and the channel pattern may be reduced. Therefore, the electrical characteristics of the vertical channel transistor of the semiconductor device may be improved.

The vertical transistor included in the semiconductor device in accordance with example embodiments may be used as a selection transistor for various memory devices other than DRAM. Additionally, the semiconductor devices in accordance with example embodiments may be used as memories included in electronic products such as mobile devices, memory cards, and computers, etc.

One or more embodiments may provide a semiconductor device including a vertical channel transistor.

Example embodiments have been disclosed herein, and although specific terms are employed, they are used and are to be interpreted in a generic and descriptive sense only and not for purposes of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor device, comprising:
a substrate;
a channel pattern on the substrate, the channel pattern having sidewalls extending in a vertical direction perpendicular to a surface of the substrate and a lower portion connecting lower portions of two sidewalls facing each other in a horizontal direction;
a gate insulation layer pattern and a first conductive layer pattern sequentially stacked laterally on an inner sidewall of the channel pattern; and
a second conductive layer pattern contacting at least an uppermost surface and an upper outer sidewall of the channel pattern, the second conductive pattern being spaced apart from the first conductive layer pattern.

2. The semiconductor device as claimed in claim 1, wherein the channel pattern includes an oxide semiconductor.

3. The semiconductor device as claimed in claim 1, wherein an uppermost surface of the first conductive layer pattern is higher than a bottom of the second conductive layer pattern.

4. The semiconductor device as claimed in claim 1, further comprising a capacitor on an upper surface of the second conductive layer pattern.

5. The semiconductor device as claimed in claim 1, wherein an uppermost surface of the first conductive layer pattern is lower than uppermost surfaces of the channel pattern and the gate insulation pattern.

6. The semiconductor device as claimed in claim 1, further comprising a mold insulation structure on an outer sidewall of the channel pattern,
wherein the mold insulation structure includes:
a lower mold insulation pattern contacting the outer sidewall of the channel pattern; and
an upper mold insulation pattern on the lower mold insulation pattern, the upper mold insulation pattern being spaced apart from the upper outer sidewall of the channel pattern.

7. The semiconductor device as claimed in claim 6, wherein:
the lower mold insulation pattern includes silicon oxide, and
the upper mold insulation pattern includes silicon nitride.

8. The semiconductor device as claimed in claim 6, wherein a bottom of the second conductive layer pattern contacts an upper surface of the lower mold insulation pattern.

9. The semiconductor device as claimed in claim 6, wherein a top surface of the second conductive layer pattern is higher than a top surface of the mold insulation structure.

10. A semiconductor device, comprising:
a substrate;
a first conductive layer pattern on the substrate, the first conductive pattern extending in a first direction parallel to an upper surface of the substrate;
a channel pattern on the first conductive layer pattern, the channel pattern having sidewalls extending in a vertical direction perpendicular to the upper surface of the substrate and a lower portion connecting lower portions of two sidewalls facing each other in the first direction, and the lower portion contacting an upper surface of the first conductive layer pattern;
a gate insulation layer pattern stacked on an inner sidewall of the channel pattern;
a second conductive layer pattern on the gate insulation layer pattern;
a mold insulation structure on an outer sidewall of the channel pattern, the mold insulation structure including a lower mold insulation pattern and an upper mold insulation pattern stacked, the upper mold insulation pattern being spaced apart from an upper outer sidewall of the channel pattern;
a third conductive layer pattern contacting at least an uppermost surface and the upper outer sidewall of the channel pattern, the third conductive layer pattern filling a space between the outer sidewall of the channel pattern and the upper mold insulation pattern; and
a capacitor contacting an upper surface of the third conductive layer pattern.

11. The semiconductor device as claimed in claim 10, wherein the channel pattern includes an oxide semiconductor.

12. The semiconductor device as claimed in claim 10, wherein an uppermost surface of the second conductive layer pattern is lower than uppermost surfaces of the channel pattern and the gate insulation pattern.

13. The semiconductor device as claimed in claim 10, wherein an uppermost surface of the second conductive layer pattern is higher than a bottom of the third conductive layer pattern.

14. The semiconductor device as claimed in claim 10, wherein:
a plurality of channel patterns are spaced apart from each other in each of the first directions and a second direction perpendicular to the first direction,
the mold insulation structure is between the first direction of the channel pattern, and extends in the second direction.

15. The semiconductor device as claimed in claim 10, wherein a bottom of the third conductive layer pattern contacts an upper surface of the lower mold insulation pattern.

16. The semiconductor device as claimed in claim 10, wherein an uppermost surface of the third conductive layer pattern is higher than an upper surface of the mold insulation structure.

17. The semiconductor device as claimed in claim 10, further comprising a filling insulation pattern on the gate insulation layer pattern and the second conductive layer pattern,
wherein the filling insulation pattern extends in a second direction perpendicular to the first direction while opposing the mold insulation structure in a horizontal direction.

18. The semiconductor device as claimed in claim 17, wherein the third conductive layer pattern fills a gap between the filling insulation pattern and the upper mold insulation pattern.

19. A semiconductor device, comprising:
a substrate;
a channel pattern on the substrate, the channel pattern having sidewalls extending in a vertical direction perpendicular to a surface of the substrate and a lower portion connecting lower portions of two sidewalls facing each other in a first direction parallel to an upper surface of the substrate;
a gate insulation layer pattern and a first conductive layer pattern sequentially stacked laterally on an inner sidewall of the channel pattern;
a mold insulation structure on an outer sidewall of the channel pattern, the mold insulation structure extending in the first direction, wherein an upper sidewall of the mold insulation structure is spaced apart from an upper outer sidewall of the channel pattern;
a filling insulation pattern on the gate insulation layer pattern and the first conductive layer pattern, the filling insulation pattern extending in a second direction perpendicular to the first direction while opposing the mold insulation structure in a horizontal direction; and
a second conductive layer pattern contacting at least an uppermost surface and an upper outer sidewall of the channel pattern, the second conductive layer pattern filling a space between the filling insulation pattern and the upper sidewall of the mold insulation structure.

20. The semiconductor device as claimed in claim 19, wherein an uppermost surface of the first conductive layer pattern is higher than a bottom of the second conductive layer pattern.
